(19) United States
(12) Patent Application Publication
(10) Pub. No.: US 2017/0261240 A1
(43) Pub. Date: Sep. 14, 2017

(54) THERMOELECTRIC CONVERSION DEVICE AND KITCHEN UNIT

(71) Applicant: Panasonic Intellectual Property Management Co., Ltd., Osaka (JP)

(72) Inventors: EIJI OKUZONO, Fukuoka (JP); TETSUYA NISHIO, Fukuoka (JP); TAKAFUMI SHINGAI, Kumamoto (JP); MASANARI ESAKI, Gunma (JP)

(21) Appl. No.: 15/421,602

(22) Filed: Feb. 1, 2017

(30) Foreign Application Priority Data
Mar. 9, 2016 (JP) 2016-045203

(51) Int. Cl. F25B 21/02; F25D 31/00; H01L 35/30

(52) U.S. Cl. CPC F25B 21/02; H01L 35/30; F25D 31/001; F25B 2321/0251; F25B 2321/0252

(57) ABSTRACT

A thermoelectric conversion device for cooling an object includes a thermoelectric converter and a structure. The thermoelectric converter has a cooling surface and a heat generating surface. The cooling surface is for cooling the object. The heat generating surface is on a side opposite to the cooling surface. The structure removes heat from the heat generating surface. The structure includes a heat transfer member, a pipe through which water flows, and a heat radiation member. The heat transfer member is joined to the heat generating surface. The pipe is disposed on the heat transfer member. The heat radiation member extends inside the pipe from the heat transfer member. A kitchen unit includes a thermoelectric conversion device, a main body, and a cooling plate. The cooling plate is disposed on an upper surface of the main body, and is cooled by the thermoelectric converter.

### BACKGROUND

1. Technical Field

The present disclosure relates to a thermoelectric conversion device, and a kitchen unit using the same.

2. Description of the Related Art

A kitchen unit such as a so-called built-in kitchen is equipped with a heating device such as an electromagnetic cooker and a gas stove. However, in cooking, not only heating food but also cooling food is sometimes required. Additionally, besides boiling water, cold water is sometimes required in order to provide cold cooking A kitchen unit equipped with a cooling device can widely respond to request of such cooking.

Unexamined Japanese Patent Publication No. 2002-315639 describes a kitchen floor cabinet capable of heating and cooling food by inverting of a polarity of power supplied to Peltier elements.

### SUMMARY

A first aspect of the present disclosure relates to a thermoelectric conversion device for cooling an object. The thermoelectric conversion device according to the first aspect includes a thermoelectric converter, and a structure. The thermoelectric converter has a cooling surface and a heat generating surface. The cooling surface is for cooling an object. The heat generating surface is on a side opposite to the cooling surface. The structure removes heat from the heat generating surface. The structure includes a heat transfer member, a pipe through which water flows, and one or more first heat radiation members. The heat transfer member is directly or indirectly joined to the heat generating surface. The pipe is disposed on the heat transfer member. The first heat radiation members extend inside the pipe from the heat transfer member.

According to the thermoelectric conversion device of this aspect, when water is allowed to flow in the pipe, heat is efficiently removed from the heat radiation members due to the water. Consequently, heat can be efficiently removed from the heat generating surface of the thermoelectric converter, and the cooling surface of the thermoelectric converter can be more efficiently held at a low temperature, compared to a case where the pipe is not provided in the structure and the heat radiation members are not cooled by water.

A second aspect of the present disclosure relates to a kitchen unit. The kitchen unit according to the second aspect includes the thermoelectric conversion device according to the first aspect, a main body, and a cooling plate. The cooling plate is disposed on an upper surface of the main body, and is cooled by the thermoelectric converter.

According to the kitchen unit of the second aspect, an effect similar to the effect of the first aspect can be exerted. Additionally, the cooling plate is efficiently cooled by the thermoelectric converter, and therefore a cooking tool such as a pan placed on the cooling plate can be efficiently cooled.

As described above, according to the thermoelectric conversion device according to the present disclosure and the kitchen unit using the same, in a case where Peltier elements are used for cooling, heat can be efficiently removed from a surface on a side opposite to a surface on a cooling side.

An effect or significance of the present disclosure will be further clarified by description of an exemplary embodiment described below. However, the exemplary embodiment described below is merely an example when the present disclosure is implemented, and the present disclosure is not limited to the following exemplary embodiment.

### BRIEF DESCRIPTION OF THE DRAWINGS

FIG. 1 is a perspective view schematically illustrating a configuration of a kitchen unit according to an exemplary embodiment;

FIG. 2 is a perspective view schematically illustrating a configuration of a cooling plate, a thermoelectric conversion device, a ring member, and a structure according to the exemplary embodiment;

FIG. 3A is an exploded perspective view schematically illustrating a configuration of a thermoelectric converter according to the exemplary embodiment;

FIG. 3B is a perspective view schematically illustrating a configuration of a completely assembled state of the thermoelectric converter according to the exemplary embodiment;

FIG. 4A is a schematic diagram illustrating a thermoelectric conversion device installed in the kitchen unit as viewed in a Y-axis positive direction, according to the exemplary embodiment;

FIG. 4B is a schematic diagram illustrating the thermoelectric conversion device installed in the kitchen unit as viewed in an X-axis negative direction, according to the exemplary embodiment;

FIG. 5A is a diagram for describing that a cooking tool such as a pan is efficiently cooled by the exemplary embodiment;

FIG. 5B is a diagram for describing that the cooking tool such as a pan is efficiently cooled by the exemplary embodiment;

FIG. 6 is a diagram schematically illustrating flow passages of tap water inside the kitchen unit according to the exemplary embodiment;

FIG. 7A is a sectional view schematically illustrating a part of a cross section of a pipe according to a variation, obtained by cutting the pipe by a plane parallel to an X-Y plane; and

FIG. 7B is a sectional view schematically illustrating a part of a cross section of a pipe according to another variation, obtained by cutting the pipe by a plane parallel to an X-Y plane.

### DETAILED DESCRIPTION OF EMBODIMENT

Prior to description of an exemplary embodiment of the present disclosure, a problem in a conventional configuration is described. In a case where Peltier elements are used to cool food and the like, heat is preferably effectively removed from a surface of the Peltier elements on a side opposite to a surface where a cooking tool such as a pan is placed. Consequently, a temperature of the surface where the cooking tool is placed can be held at a low temperature, and food and the like can be efficiently cooled. However, Unexamined Japanese Patent Publication No. 2002-315639 merely describes that heat generated from the surface of the Peltier elements on the opposite side is utilized for heat insulation of food stored in a storage space of a kitchen floor cabinet, and does not describe that heat is positively removed from the surface of the Peltier elements on the opposite side when the cooking tool is cooled.

In view of such a problem, the present disclosure provides a thermoelectric conversion device capable of efficiently removing heat from a surface on a side opposite to a surface on a cooling side in a case where Peltier elements are used for cooling, and a kitchen unit using the same.

Hereinafter, an exemplary embodiment of the present disclosure is described with reference to the drawings. For convenience, X, Y, and Z-axes orthogonal to each other are added in each drawing. An X-axis positive direction, a Y-axis positive direction, and a Z-axis positive direction are a right direction, a rear direction, and a downward direction of kitchen unit 1, respectively.

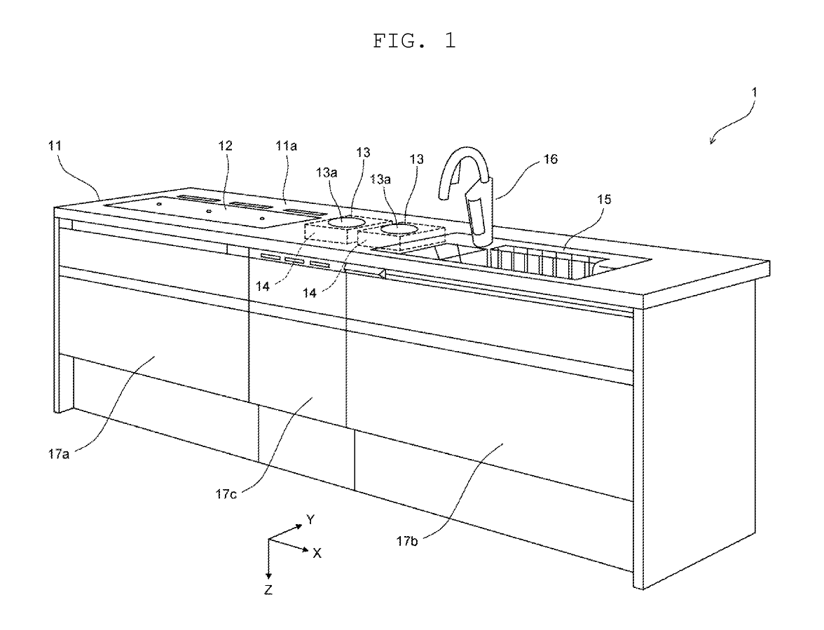

FIG. 1 is a perspective view schematically illustrating a configuration of kitchen unit 1.

As illustrated in FIG. 1, kitchen unit 1 includes main body 11, heater 12, two cooling plates 13, two thermoelectric conversion devices 14, sink 15, faucet 16, and storage parts 17a to 17c.

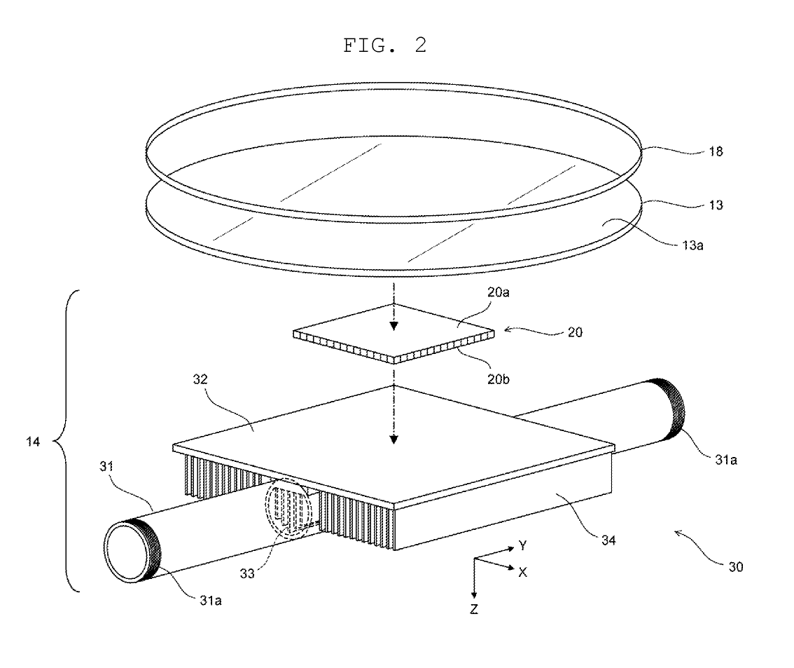

Main body 11 has a rectangular parallelepiped box shape. Heater 12 is an electromagnetic cooker installed on upper surface 11a of main body 11, and heats a metal cooking tool (such as a pan) placed on heater 12. Two cooling plates 13 are installed on upper surface 11a so as to be aligned in a right-left direction. Respective thermoelectric conversion devices 14 are installed inside main body 11 directly below two cooling plates 13. Thermoelectric conversion devices 14 cool cooling plates 13 while radiating heat by use of tap water, so that an object to be placed on each cooling plate 13 (cooking tool such as a pan) is cooled. A configuration of each thermoelectric conversion device 14 is described later with reference to FIG. 2 to FIG. 4B.

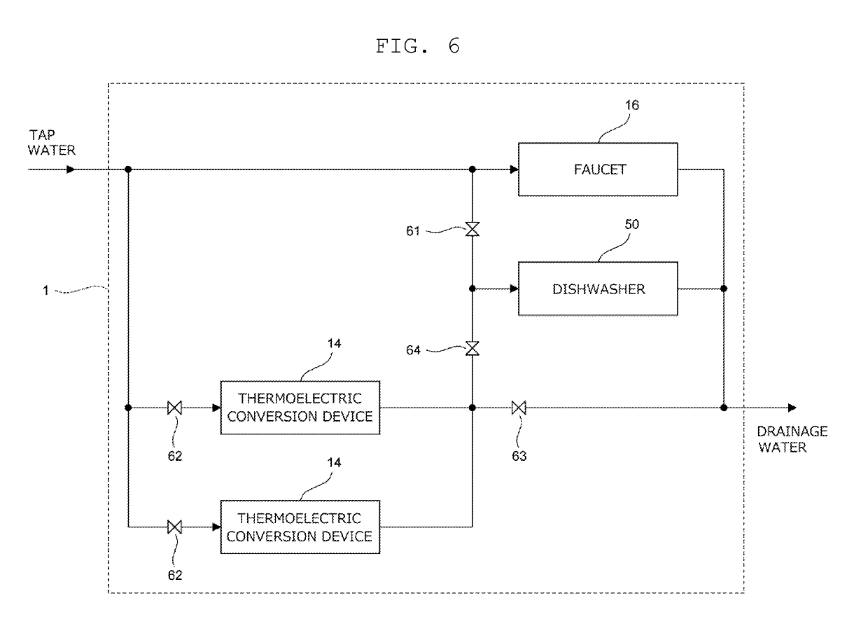

Sink 15 is formed on upper surface 11a of main body 11. Faucet 16 is installed in sink 15 to discharge tap water. Storage parts 17a, 17b are drawable in a frontward direction along rails (not illustrated). Storage parts 17a, 17b store cooking tools and the like. In storage part 17c of this exemplary embodiment, dishwasher 50 (refer to FIG. 6) described later is installed.

FIG. 2 is a perspective view schematically illustrating a configuration of cooling plate 13, thermoelectric conversion device 14, ring member 18, and structure 30.

As illustrated in FIG. 2, cooling plate 13 has a circular shape in plan view. Upper surface 13a of cooling plate 13 is a flat plane. Cooling plate 13 is formed of a material having high thermal conductivity, and resisting rust (such as aluminum and stainless steel). The thickness of cooling plate 13 is approximately 3 mm or more and 5 mm or less such that both strength and thermal conductivity become high. Thermoelectric conversion device 14 includes thermoelectric converter 20 and structure 30. Thermoelectric converter 20 has cooling surface 20a for cooling an object, and heat generating surface 20b located on a side opposite to cooling surface 20a. Cooling surface 20a is corresponding to an upper surface of thermoelectric converter 20, and heat generating surface 20b is corresponding to a lower surface of thermoelectric converter 20.

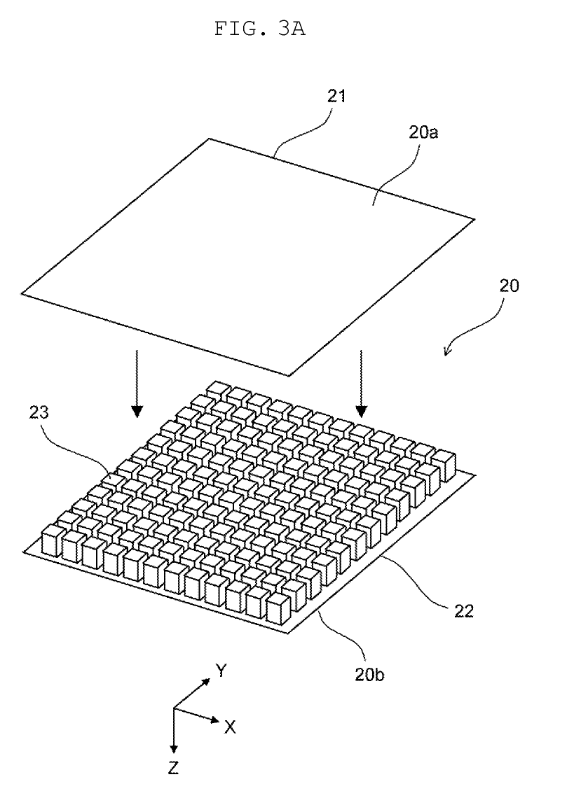

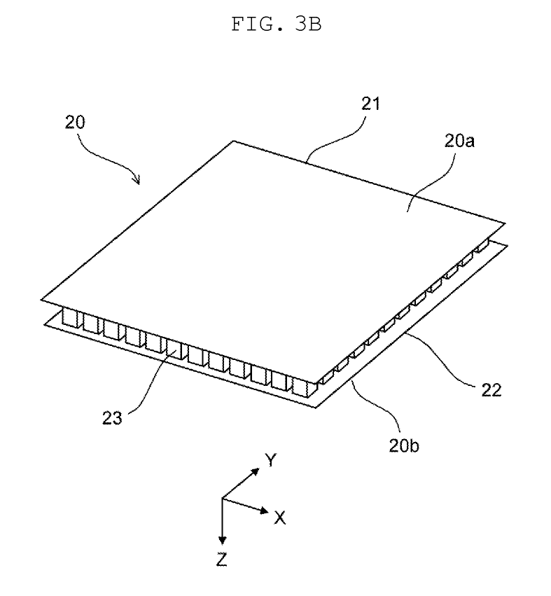

FIG. 3A is an exploded perspective view schematically illustrating a configuration of thermoelectric converter 20, and FIG. 3B is a perspective view schematically illustrating a configuration of a completely assembled state of thermoelectric converter 20.

As illustrated in FIG. 3A, thermoelectric converter 20 includes first substrate 21, second substrate 22, and thermoelectric conversion elements 23.

First substrate 21 and second substrate 22 each have a substantially square shape in plan view, and are formed of a metal material having high thermal conductivity. As illustrated in FIG. 3A, in a state where thermoelectric conversion elements 23 are disposed on an upper surface of second substrate 22, first substrate 21 is overlapped on upper surfaces of thermoelectric conversion elements 23. Thermoelectric conversion elements 23 are arranged in an X-axis direction and in a Y-axis direction with constant pitches. Thermoelectric conversion elements 23 are for transferring heat based on applied power to cool, and, for example, composed of Peltier elements.

Respective connection electrodes (not illustrated) joined to upper electrodes and lower electrodes of thermoelectric conversion elements 23 are formed on a lower surface of first substrate 21 and the upper surface of second substrate 22. A voltage is applied to thermoelectric conversion elements 23 through these connection electrodes. When a voltage is applied from a terminal (not illustrated) to thermoelectric converter 20 assembled as illustrated in FIG. 3B, the connection electrodes formed on first substrate 21 and the connection electrodes formed on second substrate 22 are set such that a voltage is uniformly applied to all thermoelectric conversion elements 23.

In assembling, in a state where the connection electrodes on the upper surface of second substrate 22 are coated with solder, thermoelectric conversion elements 23 are disposed, as illustrated in FIG. 3A. Furthermore, in a state where the connection electrodes on the lower surface of first substrate 21 are coated with solder, first substrate 21 is overlapped on the upper surfaces of thermoelectric conversion elements 23, as illustrated in FIG. 3B. In this state, reflow treatment for fusing solder is performed. Accordingly, the respective connection electrodes are joined to thermoelectric conversion elements 23, so that first substrate 21 and second substrate 22 are fixed. In such a manner, thermoelectric converter 20 illustrated in FIG. 3B is configured. When a voltage is applied to thermoelectric converter 20, heat of cooling surface 20a of thermoelectric converter 20 (upper surface of first substrate 21) is transferred to heat generating surface 20b of thermoelectric converter 20 (lower surface of second substrate 22).

Returning to FIG. 2, structure 30 removes heat from heat generating surface 20b of thermoelectric converter 20. Structure 30 is formed of a material having high thermal conductivity and resisting rust. In this exemplary embodiment, structure 30 is formed of aluminum. Structure 30 includes pipe 31, heat transfer member 32, a plurality of heat radiation members 33, and a plurality of heat radiation members 34. Each of heat radiation members 33 is corresponding to a “first heat radiation member” recited in the claims, and each of heat radiation members 34 is corresponding to a “second heat radiation member” recited in the claims.

Pipe 31 has a circular cross section. The diameter of pipe 31 is a diameter of a standard pipe used at home for transporting tap water. Near both ends of pipe 31, screw grooves 31a are formed in a circumferential direction. Heat transfer member 32 has a substantially square shape in plan view, and is disposed on an upper part of pipe 31. The width (length in the X-axis direction) of heat transfer member 32 is longer than the width (length in the X-axis direction) of pipe 31. The length in the Y-axis direction of heat transfer member 32 is shorter than the length in a longitudinal direction (Y-axis direction) of pipe 31.

Heat radiation members 33, 34 are each formed of a plate body, which has a flat plate shape, extending in the longitudinal direction (Y-axis direction) of pipe 31, and each extend in the downward direction (Z-axis positive direction) from a lower surface of heat transfer member 32 such that a main surface (a surface having the largest area) of the plate body is substantially parallel to the longitudinal direction of pipe 31. That is, heat radiation members 33, 34 each are a plate body which is parallel to a Y-Z plane. Heat radiation members 33 extend inside pipe 31 from a region of heat transfer member 32 which is connected to pipe 31, and heat radiation members 34 extend in the downward direction (Z-axis positive direction) outside pipe 31 from regions of heat transfer member 32 which are not connected to pipe 31. The plurality of heat radiation members 33 are disposed inside pipe 31 so as to be arranged in a width direction (X-axis direction) of pipe 31 with predetermined intervals, and the plurality of heat radiation members 34 are disposed outside pipe 31 so as to be arranged in the width direction (X-axis direction) of pipe 31 with predetermined intervals. Heat radiation members 33 are disposed so as to be in contact with tap water, and therefore surfaces of heat radiation members 33 are subjected to alumite treatment in order to prevent deterioration.

In this exemplary embodiment, pipe 31, heat transfer member 32, and heat radiation members 33, 34 are formed so as to continuously extend in the X-axis direction. Therefore, a die is pulled out in the Y-axis direction in molding by the die, so that it is possible to mold structure 30 in which pipe 31, heat transfer member 32, and heat radiation members 33, 34 are integrally formed. After structure 30 is molded, the both ends of pipe 31 are subjected to threading treatment, so that screw grooves 31a are formed. Then, a lower surface of thermoelectric converter 20 (heat generating surface 20b) is joined to an upper surface of heat transfer member 32, so that thermoelectric conversion device 14 is completed.

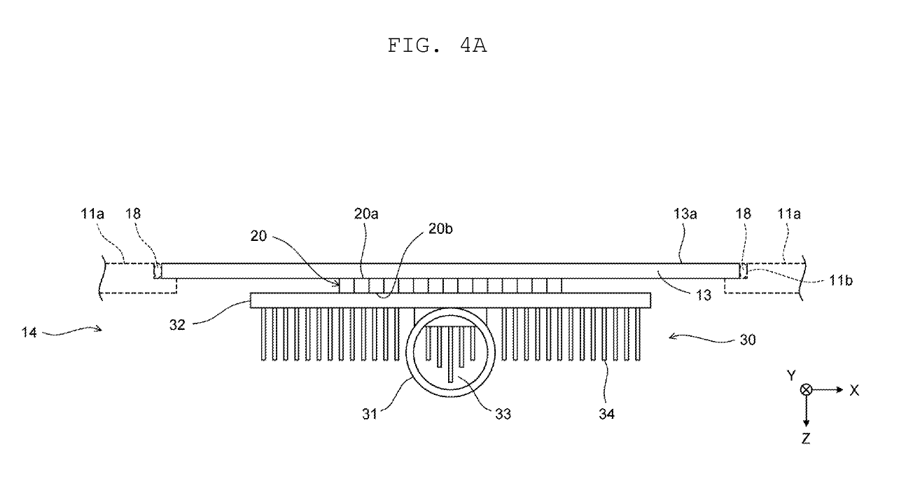

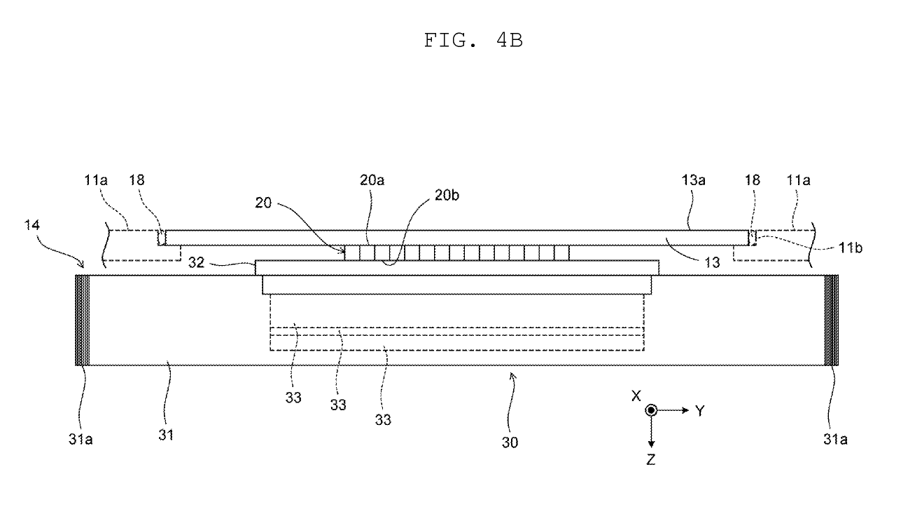

When kitchen unit 1 is assembled, each thermoelectric conversion device 14 is installed inside main body 11 in FIG. 1. At this time, screw grooves 31a of the both ends of pipe 31 are connected to pipes for transporting tap water in main body 11 by use of fixing screws. Then, cooling plate 13 is installed on upper surface 11a of main body 11 through ring member 18. Ring member 18 is formed of rubber or resin having a waterproof effect. When thermoelectric conversion device 14, cooling plate 13, and ring member 18 are installed, a lower surface of cooling plate 13 and an upper surface (cooling surface 20a) of thermoelectric converter 20 are joined to each other. Thus, as illustrated in FIG. 4A and FIG. 4B, thermoelectric conversion device 14 is installed in kitchen unit 1.

FIG. 4A and FIG. 4B are diagrams schematically illustrating thermoelectric conversion device 14 installed in kitchen unit 1 as viewed in the Y-axis positive direction and the X-axis negative direction, respectively. In FIG. 4B, illustration of heat radiation member 34 is omitted for convenience. As illustrated in FIG. 4A and FIG. 4B, cooling plate 13 is installed in circular opening 11b formed in upper surface 11a of main body 11, and upper surface 13a of cooling plates 13 and upper surface 11a of main body 11 are at the same level. Ring member 18 is installed between a side surface of cooling plate 13 and opening 11b such that no clearance is generated between cooling plate 13 and opening 11b. Additionally, the lower surface of cooling plate 13, and the upper surface (cooling surface 20a) of thermoelectric converter 20 are joined to each other. The lower surface of thermoelectric converter 20 (heat generating surface 20b) and the upper surface of heat transfer member 32 of structure 30 are joined to each other. The upper surface and the lower surface of thermoelectric converter 20 are joined to the lower surface of cooling plate 13 and the upper surface of heat transfer member 32, respectively, through, for example, gel having high thermal conductivity.

As illustrated in FIG. 4A, in this exemplary embodiment, five heat radiation members 33 are disposed inside pipe 31. In five heat radiation members 33, the length protruding inside pipe 31 of heat radiation member 33 located closer to the center in the X-axis direction of pipe 31 is longer. More specifically, among five heat radiation members 33, heat radiation member 33 located at the center in the X-axis direction of pipe 31 extends most downward. The lengths of heat radiation members 33 protruding downward are shortened toward outside of pipe 31 from heat radiation member 33 located at the center.

When thermoelectric converter 20 is driven, the heat of cooling plate 13 is transferred to structure 30. At this time, if heat radiation efficiency of structure 30 is poor, heat is saturated in structure 30, and cooling efficiency of cooling plate 13 by thermoelectric converter 20 is lowered. In particular, as illustrated in FIG. 3A, in a case where thermoelectric converter 20 is configured by integration of a large number of thermoelectric conversion elements 23, heat is likely to be concentrated near the center of the lower surface of thermoelectric converter 20 (surface on a Z-axis positive side). Accordingly, heat near the center of thermoelectric converter 20 needs to be particularly efficiently removed by structure 30.

In this exemplary embodiment, as described below, heat radiation efficiency of structure 30 is enhanced, and therefore cooling efficiency of cooling plate 13 by thermoelectric converter 20 is highly maintained.

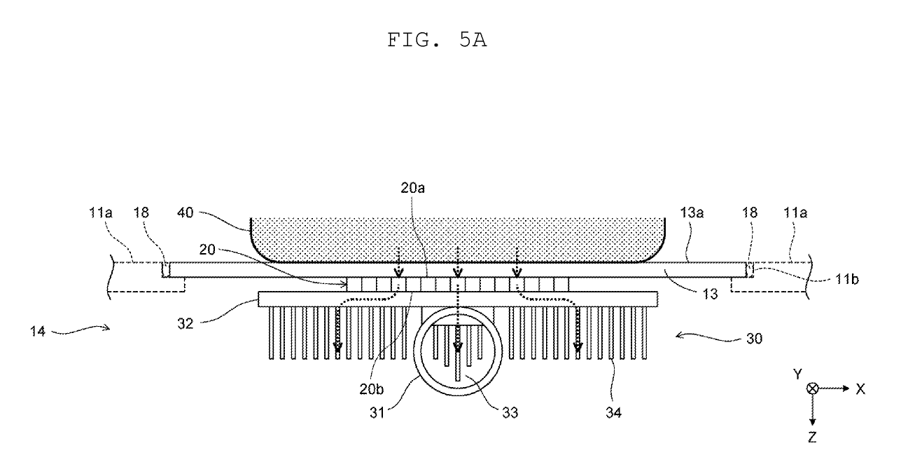

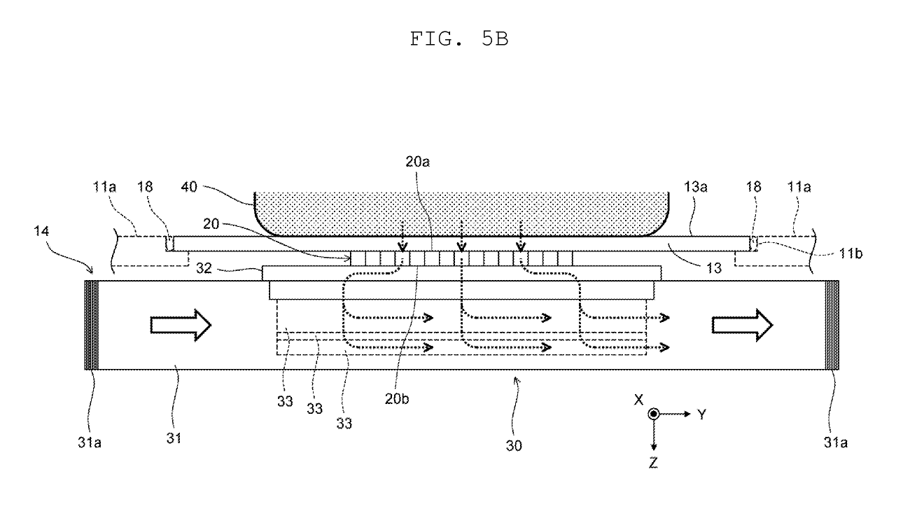

FIG. 5A and FIG. 5B each are a diagram for describing that cooking tool 40 such as a pan is efficiently cooled. FIG. 5A and FIG. 5B correspond to states illustrated in FIG. 4A and FIG. 4B, respectively.

In a case where thermoelectric conversion device 14 is used, thermoelectric converter 20 is driven, tap water flows through pipe 31 in the Y-axis positive direction. In this state, when cooking tool 40 as an object is placed on upper surface 13a of cooling plates 13, as illustrated in dotted arrows in FIG. 5A and FIG. 5B, heat of cooking tool 40 is led to the upper surface (cooling surface 20a) of thermoelectric converter 20 through cooling plate 13 by thermoelectric converter 20. Thermoelectric converter 20 transfers the heat led to cooling surface 20a to the lower surface of thermoelectric converter 20 (heat generating surface 20b). The heat of heat generating surface 20b is transferred to heat transfer member 32 of structure 30.

In this exemplary embodiment, the heat transferred to heat transfer member 32 is further transferred to heat radiation members 33, 34. The heat transferred to heat radiation members 33 is radiated in the Y-axis positive direction by tap water flowing in pipe 31, as illustrated in FIG. 5B. Additionally, the heat transferred to heat radiation members 34 is radiated to air near structure 30, as illustrated in FIG. 5A. Thus, in this exemplary embodiment, heat radiation efficiency of structure 30 is enhanced, and therefore cooling efficiency of cooling plate 13 and cooking tool 40 by thermoelectric converter 20 is highly maintained. Particularly, a central position of heat transfer member 32, on which heat is likely to be concentrated, is cooled with high heat radiation efficiency by flow of the tap water. Accordingly, it is possible to effectively cool cooking tool 40.

FIG. 6 is a diagram schematically illustrating flow passages of tap water inside kitchen unit 1.

As illustrated in FIG. 6, inside kitchen unit 1, in addition to two thermoelectric conversion devices 14 and faucet 16 illustrated in FIG. 1, dishwasher 50 is installed. Additionally, inside kitchen unit 1, a pipe forming the flow passages for transporting tap water, and valves 61 to 64 are provided. In FIG. 6, the flow passages are illustrated by solid lines. Valves 61 to 64 electromagnetically openably close the flow passages. In a case where thermoelectric conversion devices 14 are not used, valves 61, 63 are in an open state, valves 62, 64 are in a closed state.

New tap water led indoors (hereinafter, simply referred to as “new tap water”) is supplied to kitchen unit 1. When a user operates faucet 16, the new tap water is supplied into faucet 16, and is discharged from faucet 16. Tap water discharged from faucet 16 to be received by sink 15 is exhausted as drainage water from kitchen unit 1. When the user drives dishwasher 50, new tap water is supplied into dishwasher 50. The tap water used in dishwasher 50 is exhausted as drainage water from kitchen unit 1.

In a case where thermoelectric conversion devices 14 are used, the user operates an operation panel (not illustrated) to start cooling by thermoelectric conversion devices 14. Consequently, thermoelectric converters 20 are driven, and valves 62 are brought into an open state. Since valves 62 are opened, new tap water is supplied to thermoelectric conversion devices 14. As illustrated in FIG. 5B, while the tap water supplied to thermoelectric conversion devices 14 advances inside pipe 31 in a downstream direction (Y-axis positive direction), heat is taken from heat radiation members 33. The tap water that advances pipes 31 in the downstream direction to be exhausted from thermoelectric conversion devices 14 passes through valve 63 to be exhausted as drainage water from kitchen unit 1.

The tap water supplied to thermoelectric conversion devices 14 simply flow in pipes 31 to be utilized for heat radiation. Therefore, it can be said that there is almost no sanitary difference between tap water exhausted from thermoelectric conversion devices 14 and new tap water. Kitchen unit 1 of this exemplary embodiment is configured such that tap water exhausted from thermoelectric conversion devices 14 can be reused in dishwasher 50.

In a case where tap water exhausted from thermoelectric conversion devices 14 illustrated in FIG. 5B and FIG. 6 is reused in dishwasher 50, the user operates the operation panel (not illustrated), and sets a reuse mode to start cooling by thermoelectric conversion devices 14. Consequently, thermoelectric converters 20 are driven, and tap water used for cooling of thermoelectric converters 20 is exhausted from thermoelectric conversion devices 14. At this time, in a period during which water is supplied to dishwasher 50, valve 64 is in an open state and valves 61, 63 are in a closed state. Valves 62 are each maintained in an open state in a period during which cooling operation by thermoelectric conversion devices 14 is performed. Consequently, the tap water exhausted from thermoelectric conversion devices 14 is supplied to dishwasher 50 through valve 64. In a period during which water is not supplied to dishwasher 50, valve 64 is closed and valve 63 is opened. Consequently, the tap water exhausted from thermoelectric conversion devices 14 is exhausted through valve 63.

In a case where the use of thermoelectric conversion devices 14 is terminated, the user operates the operation panel (not illustrated), and terminates cooling by thermoelectric conversion devices 14. Consequently, the drive of thermoelectric converters 20 is stopped, valves 62, 64 are brought into a closed state, and valves 61, 63 are brought into an open state. Since valves 62 are closed, the supply of new tap water to thermoelectric conversion devices 14 is stopped. New tap water is supplied to dishwasher 50 through valve 61.

The above control is performed by a controller (not illustrated) of kitchen unit 1.

Cooling by two thermoelectric conversion devices 14 can be individually performed. In this case, the user operates the operation panel (not illustrated), and sets thermoelectric conversion device 14 of which cooling is to be started, and starts cooling of thermoelectric conversion device 14. Consequently, among two valves 62, only the valve corresponding to set thermoelectric conversion device 14 is brought into an open state, and new tap water is supplied only to set thermoelectric conversion device 14.

### ADVANTAGEOUS EFFECTS OF EXEMPLARY EMBODIMENT

As described above, according to this exemplary embodiment, the following advantageous effects are exerted.

When each thermoelectric converter 20 illustrated in FIG. 5B is driven and tap water flows in pipe 31, heat is efficiently removed from heat radiation members 33 by the tap water. Consequently, compared to a case where pipe 31 is not provided in structure 30 and heat radiation members 33 are not cooled by tap water, heat can be efficiently removed from heat generating surface 20b of thermoelectric converter 20. Accordingly, cooling surface 20a of thermoelectric converter 20 can be more efficiently held at a low temperature. Additionally, because cooling surface 20a is efficiently held at a low temperature, an object placed on upper surface 13a of cooling plate 13 can be efficiently cooled.

Pipe 31, heat transfer member 32, heat radiation members 33, 34 illustrated in FIG. 5A are integrally formed by a material having high thermal conductivity, and therefore a clearance is unlikely to be generated between pipe 31 and heat transfer member 32 compared to a case where the respective members are assembled to be joined to each other. Consequently, water leakage from pipe 31 is unlikely to occur. Additionally, because the respective members are integrally formed, structure 30 can be simply produced and the reduction in cost can be attained. In this specification, the “material having high thermal conductivity” means a material having thermal conductivity such as a metal material and a ceramic material, which is a material whose thermal conductivity is approximately 1.0 W/(m·K) or more. As the “material having high thermal conductivity”, a material whose thermal conductivity is 10.0 W/(m·K) or more is preferable, and a material whose thermal conductivity is 100.0 W/(m·K) or more is more preferable.

Heat radiation members 33 are each formed of a plate body having a flat plate shape, and are formed inside pipe 31 such that the main surface of the plate body is substantially parallel to the longitudinal direction (tap water flow direction) of pipe 31. Consequently, tap water can be allowed to smoothly flow inside pipe 31 while areas of heat radiation members 33 for heat radiation can be widely ensured. Additionally, the plurality of heat radiation members 33 are disposed inside pipe 31 so as to be arranged in the width direction of pipe 31 at predetermined intervals. Consequently, it is possible to ensure wider areas for heat radiation, and it is possible to enhance heat radiation efficiency.

Five heat radiation members 33 are disposed inside pipe 31. In five heat radiation members 33, the length protruding inside pipe 31 located closer to the center in the width direction of pipe 31 is longer. Consequently, heat radiation members 33 can be efficiently disposed inside pipe 31. Additionally, compared to a case where the lengths of heat radiation members 33 are uniform, turbulence is unlikely to occur inside pipe 31. Therefore, the heat of heat generating surface 20b of thermoelectric converter 20 can be stably radiated by heat radiation members 33.

In the regions of heat transfer member 32 which are not joined to pipe 31, heat radiation members 34 are provided separately from heat radiation members 33. Consequently, it is possible to more efficiently radiate heat from heat generating surface 20b of thermoelectric converter 20.

Upper surface 13a of cooling plate 13 and upper surface 11a of main body 11 are disposed at the same level. Consequently, cooking tool 40 such as a pan is easily placed on upper surface 13a of cooling plate 13. Additionally, upper surface 13a of cooling plate 13 is a flat plane. Consequently, when cooking tool 40 such as a pan is placed on upper surface 13a, a contact area between the bottom of cooking tool 40 and upper surface 13a increases and thus the contact between them becomes satisfactory. Accordingly, it is possible to efficiently facilitate cooling of cooking tool 40.

On an outer periphery of cooling plate 13, ring member 18 for waterproof is installed. Consequently, no clearance exists between the outer periphery of cooling plate 13 and opening 11b of upper surface 11a, and therefore it is possible to prevent water leakage to inside of main body 11.

Tap water exhausted from thermoelectric conversion device 14 can be supplied to dishwasher 50. Consequently, an amount of tap water used in kitchen unit 1 can be suppressed, and influence on an environment can be suppressed. Additionally, the tap water exhausted from thermoelectric conversion device 14 absorbs heat, and therefore has a higher temperature, compared to new tap water. Therefore, when the tap water exhausted from thermoelectric conversion device 14 is used in dishwasher 50, power consumption of dishwasher 50 can be reduced.

Heat radiation members 33 are cooled by tap water flowing in pipe 31, and therefore the vertical length of thermoelectric conversion device 14 can be minimized. For example, in a case where the heat radiation members are cooled by air sent from a fan disposed below the heat radiation members, the vertical size of the thermoelectric conversion device is increased due to the disposed fan. However, according to this exemplary embodiment, no fan needs to be disposed, and therefore thermoelectric conversion device 14 can be downsized. Consequently, it is possible to reduce a space occupied by thermoelectric conversion device 14 inside main body 11 of kitchen unit 1.

The diameter of pipe 31 is the diameter of a standard pipe used at home for transporting tap water. Therefore, pipe 31 can be easily connected to the standard pipe through which tap water flows, without a component for matching the diameter.

Structure 30 is formed of aluminum. Aluminum generally has high thermal conductivity, and is light in weight, is easily molded, and resists rust. Therefore, the thermal conductivity of structure 30 can be increased, the weight of structure 30 can be reduced, structure 30 can be easily molded, and structure 30 can resist rust.

### <Variations>

The exemplary embodiment of the present disclosure has been described above, but the present disclosure is not limited to the above exemplary embodiment.

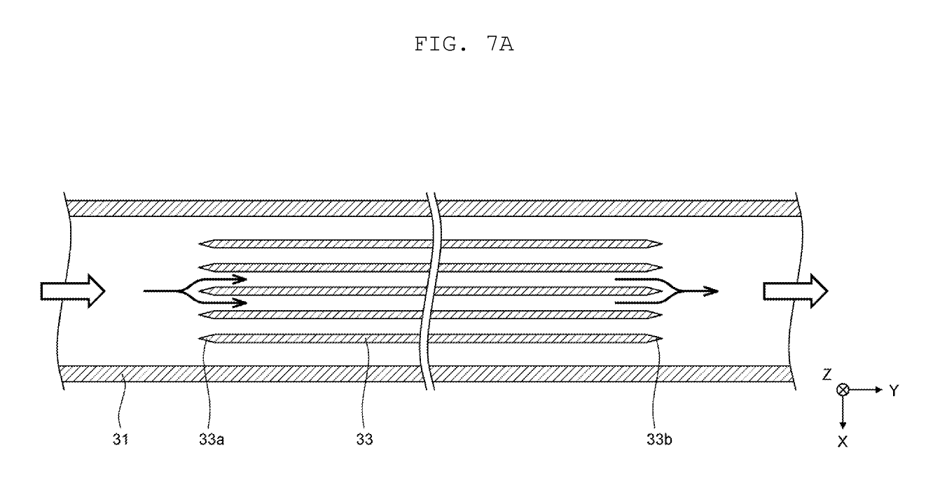

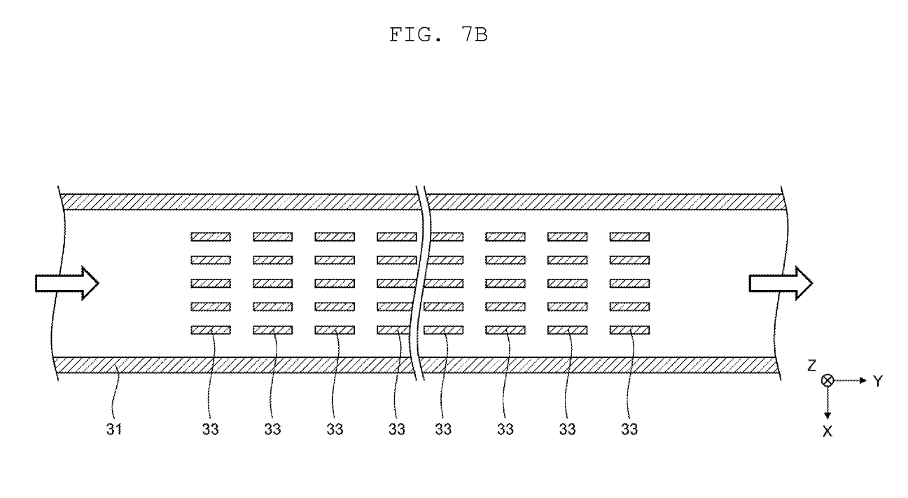

For example, in the above exemplary embodiment, the end surfaces on the Y-axis positive side and the Y-axis negative side of each heat radiation member 33 are a plane parallel to an X-Z plane, as illustrated in FIG. 4A and FIG. 4B. However, the present disclosure is not limited to this, and the thicknesses of end portion 33a on a water flow upstream side (Y-axis negative side) of each of heat radiation members 33 may be decreased toward an upstream side, as illustrated in FIG. 7A. That is, the thickness of each of heat radiation members 33 decreases toward an upstream of flow of the water in end portion 33a on the upstream side (Y-axis negative side) of each of heat radiation members 33. Additionally, the thickness of each of heat radiation members 33 decreases toward a downstream of flow of the water in end portion 33b on a downstream side (Y-axis positive side) of each of heat radiation members 33.

FIG. 7A is a sectional view schematically illustrating a part of a cross section of pipe 31, obtained by cutting pipe 31 by a plane parallel to the X-Y plane. As illustrated in FIG. 7A, each of end portions 33a, 33b of heat radiation members 33 of this variation is constituted by two end surfaces which are inclined to the X-axis positive side and the X-axis negative side, respectively, from a plane parallel to the Y-Z plane. When tap water flows toward end portions 33a that are formed as described above, the flow is unlikely to be inhibited by colliding with the end surfaces of end portions 33a. When tap water flows away from end portions 33b, the flow of tap water is unlikely to be disturbed by the end surfaces of end portions 33b. Accordingly, tap water can be allowed to smoothly flow in pipe 31, and therefore it is possible to enhance the cooling performance of thermoelectric conversion devices 14.

In the above exemplary embodiment, pipe 31, heat transfer member 32, heat radiation members 33, and heat radiation members 34 are integrally formed. However, these members may be separately formed, and the formed members may be joined by welding or the like. That is, a configuration of structure 30 is not limited to the integrally formed configuration, and structure 30 may be formed by assembling the respective members by welding. In a case where structure 30 is completed by assembling the respective members, the respective members can be more complicatedly molded compared to a case of being integrally formed. For example, heat radiation members 33 may not continuously extend in the Y-axis direction, and therefore the plurality of heat radiation members 33 can be disposed in the Y-axis direction, as illustrated in FIG. 7B.

FIG. 7B is a sectional view schematically illustrating a part of a cross section of pipe 31, obtained by cutting pipe 31 by a plane parallel to the X-Y plane. As illustrated in FIG. 7B, the lengths in the Y-axis direction of heat radiation members 33 of this variation are shorter than those in the above exemplary embodiment, and the plurality of heat radiation members 33 are arranged in the Y-axis direction. Heat radiation members 33 of this variation are also configured such that the length in the Z-axis direction of heat radiation member 33 located closer to the center in the X-axis direction of pipe 31 is longer. Structure 30 (refer to FIG. 5A) of this variation is configured such that, for example, pipe 31 having an opening at the upper part, and heat transfer member 32 provided with heat radiation members 33, 34 on a lower surface side are joined by welding or the like.

When heat radiation members 33 are thus provided, tap water can be allowed to flow also between adjacent heat radiation members 33 in the Y-axis direction. However, the respective members need to be carefully joined by welding or the like such that tap water in pipe 31 does not leak. Therefore, structure 30 is desirably integrally formed like the above exemplary embodiment.

In the above exemplary embodiment, five heat radiation members 33 are disposed inside pipe 31 as illustrated in FIG. 4A. However, one to four heat radiation members 33 may be disposed, or six or more heat radiation members 33 may be disposed. In a case where three or more heat radiation members 33 are disposed inside pipe 31, heat radiation members 33 are desirably configured such that the length protruding inside pipe 31 of heat radiation member 33 located closer to the center in the X-axis direction of pipe 31 is longer, similarly to the above exemplary embodiment. That is, heat radiation members 33 are disposed such that the length protruding inside the pipe of heat radiation member 33 located closer to the center in the width direction of pipe 31 is longer.

In the above exemplary embodiment, heat radiation members 33 are the plate bodies parallel to the Y-Z plane. However, heat radiation members 33 are not limited to these, and only need to be formed so as to extend inside pipe 31 from heat transfer member 32. However, heat radiation members 33 are desirably formed so as to extend in a tap water flow direction (Y-axis direction) so as not to prevent the flow of tap water. For example, heat radiation members 33 may be cylindrical members extending in the Y-axis direction. Additionally, heat radiation members 34 are plate bodies parallel to the Y-Z plane. However, heat radiation members 34 are not limited to these, and only need to be formed so as to extend in the downward direction (Z-axis positive direction) from heat transfer member 32. A large number of columnar protrusions may be formed so as to extend in the downward direction (Z-axis positive direction) from heat transfer member 32.

In the above exemplary embodiment, the diameter of pipe 31 is the diameter of a standard pipe used at home for transporting tap water. However, the diameter of pipe 31 is not limited to this, and may not be the diameter of the standard pipe. However, in this case, a component for matching the diameter needs to be used, and therefore the diameter of pipe 31 is desirably the diameter of the standard pipe as in the above exemplary embodiment.

The diameter of pipe 31 may not be always constant in a whole length. For example, the width in the X-axis direction of a part where heat radiation members 33 are disposed may be widened. Consequently, a larger number of heat radiation members 33 can be disposed inside pipe 31. In this case, pipe 31 is desirably formed such that the width in the X-axis direction is gradually narrowed from the part having the widened width toward the both ends of pipe 31 in order to allow tap water to smoothly flow.

In the above exemplary embodiment, structure 30 is formed of aluminum. However, structure 30 may be formed of other material (such as copper). In a case where structure 30 is formed of copper, thermal conductivity of structure 30 is enhanced, but structure 30 easily rusts due to tap water. Therefore, structure 30 may be desirably formed of a material which resists rust such as aluminum.

In the above exemplary embodiment, heat transfer member 32 is directly joined to heat generating surface 20b of thermoelectric converter 20. However, heat transfer member 32 may be indirectly joined to heat generating surface 20b through other member.

In the above exemplary embodiment, kitchen unit 1 is formed such that tap water exhausted from thermoelectric conversion device 14 can be reused only in dishwasher 50. However, kitchen unit 1 is not limited to this, and may be configured such that tap water exhausted from thermoelectric conversion device 14 can be supplied to faucet 16.

In the above exemplary embodiment, tap water that flows in pipe 31 is new tap water. However, liquid that flows in pipe 31 is not limited to this, and may be tap water discharged from faucet 16 to be used, or may be tap water after use in dishwasher 50. However, heat radiation members 33 are disposed inside pipe 31, and therefore it is desirable that new tap water, not tap water already used and containing impurities, flow in pipe 31. Additionally, new tap water has a relatively low temperature, and therefore when new tap water flows in pipe 31, the cooling efficiency of thermoelectric conversion devices 14 is enhanced.

The exemplary embodiment of the present disclosure can be suitably variously changed within the scope of technical ideas recited in the claims.

What is claimed is:

1. A thermoelectric conversion device for cooling an object, the device comprising:
a thermoelectric converter having a cooling surface and a heat generating surface, the cooling surface being for cooling the object, the heat generating surface being on a side opposite to the cooling surface; and
a structure for removing heat from the heat generating surface,
wherein the structure includes:
a heat transfer member directly or indirectly joined to the heat generating surface;
a pipe through which water flows, the pipe being disposed on the heat transfer member; and
one or more first heat radiation members extending inside the pipe from the heat transfer member.

2. The thermoelectric conversion device according to claim 1, wherein
the pipe, the heat transfer member, and the first heat radiation members are integrally formed of a material having high thermal conductivity.

3. The thermoelectric conversion device according to claim 1, wherein
each of the first heat radiation members is constituted from a plate body having a flat plate shape, and is disposed inside the pipe such that a main surface of the plate body is parallel to a longitudinal direction of the pipe.

4. The thermoelectric conversion device according to claim 3, wherein
a plurality of the first heat radiation members are disposed inside the pipe so as to be arranged in a width direction with an interval, the width direction being orthogonal to the longitudinal direction.

5. The thermoelectric conversion device according to claim 4, wherein:
the pipe has a circular cross section, and
three or more of the first heat radiation members are arranged in the width direction inside the pipe such that lengths of the first heat radiation members which protrude inside the pipe increase toward a center in the width direction.

6. The thermoelectric conversion device according to claim 3, wherein
a thickness of each of the first heat radiation members decreases toward an upstream of flow of the water in an end portion on an upstream side of the each of the first heat radiation members.

7. The thermoelectric conversion device according to claim 1, wherein:
a length of the heat transfer member in a width direction is larger than a width of the pipe, the width direction being orthogonal to a longitudinal direction of the pipe, and
a second heat radiation member is provided in a region of the heat transfer member, where the pipe is not disposed on.

8. A kitchen unit comprising:
the thermoelectric conversion device according to claim 1;
a main body; and
a cooling plate disposed on an upper surface of the main body, and cooled by the thermoelectric converter.

9. The kitchen unit according to claim 8, wherein
an upper surface of the cooling plate and the upper surface of the main body are disposed at an identical level.

10. The kitchen unit according to claim 8, wherein
an upper surface of the cooling plate is a flat plane.

11. The kitchen unit according to claim 8, wherein
a ring member for waterproof is installed on an outer periphery of the cooling plate.
